(19) United States
(12) Patent Application Publication
(10) Pub. No.: US 2025/0007145 A1
(43) Pub. Date: Jan. 2, 2025

(54) STACKED CHIPS WITH EDGE MOUNTED ANTENNAS FOR SMALL PITCH PHASED ARRAYS

(71) Applicant: Intel Corporation, Santa Clara, CA (US)

(72) Inventors: Peter BAUMGARTNER, Munich (DE); Richard GEIGER, Munich (DE); Georgios C. DOGIAMIS, Chandler, AZ (US); Steven CALLENDER, Denver, CO (US); Telesphor KAMGAING, Chandler, AZ (US); Jonathan C. JENSEN, Greenville, SC (US); Harald GOSSNER, Riemerling (DE)

(21) Appl. No.: 18/216,315

(22) Filed: Jun. 29, 2023

(51) Int. Cl. H01Q 1/22; H01L 25/10; H01Q 21/24

(52) U.S. Cl. CPC H01Q 1/2283; H01L 25/105; H01Q 21/24

(57) ABSTRACT

Embodiments disclosed herein include communication dies for mm-wave and/or sub-terahertz wavelength communications. In an embodiment, a communications die comprises a substrate with a first face and a second face. In an embodiment, edge surfaces connect the first face to the second face. In an embodiment, a circuitry element is on the first face, and an antenna on at least one of the edge surfaces.

### TECHNICAL FIELD

Embodiments of the present disclosure relate to electronic systems, and more particularly, to communication modules with three-dimensional antenna arrays.

### BACKGROUND

Communication modules are of increasing importance as wireless communications continue to proliferate. Generally, a communication module includes a transceiver die (i.e., a die that is compatible to receive communications (Rx) and compatible to transmit communications (Tx)). In an effort to improve bandwidth of the wireless communications, protocols are moving to smaller wavelengths. mm-wave wireless transmission and sub-terahertz wireless transmission are examples of such wireless solutions.

For mm-wave and sub-THz wireless transmission, the increased carrier frequencies pose several challenges regarding the achievable signal power at the receiver. For example, the increasing attenuation for free-space propagation or the reduced achievable output power per CMOS transmitter blocks are some limiting factors. Therefore, beam forming is a common approach to boost the achievable receive power. The beam steering functionality is typically achieved by implementation of two-dimensional phased arrays. These allow for beam steering with some angular range, such that multiple modules are needed for a larger angular coverage.

Such phased arrays are typically arranged in a pattern that includes antennas at a pitch of λ/2 where λ is the operational wavelength of the antennas. This becomes problematic when the wavelength decreases. Particularly, when the pitch is smaller than the size of the Tx/Rx circuitry, there are integration issues. Accordingly, two-dimensional arrays may not be suitable for advanced communication modules.

### BRIEF DESCRIPTION OF THE DRAWINGS

FIG. 1A is a plan view illustration of a communication module with a plurality of antennas in a two-dimensional array with Tx/Rx driving circuitry integrated into the array.

FIG. 1B is a plan view illustration of a communication module with a Tx/Rx driving circuitry underlying individual antennas in an array, in accordance with an embodiment.

FIG. 2 is a perspective view illustration of a three-dimensional (3D) communication die with the Tx/Rx driving circuitry on a face of the die with antennas along edges of the die, in accordance with an embodiment.

FIG. 3 is a perspective view illustration of a communication module with a plurality of 3D communication dies with antennas along edge surfaces of the dies, in accordance with an embodiment.

FIG. 4 is a perspective view illustration of a communication module with a pair of 3D communication dies in a back-to-back configuration, in accordance with an embodiment.

FIG. 5 is a perspective view illustration of a communication module with a plurality of 3D communication dies with antennas that are positioned with an offset with respect to each other, in accordance with an embodiment.

FIG. 6 is a perspective view illustration of a communication module with an array of 3D communication dies, in accordance with an embodiment.

FIG. 7 is a cross-sectional illustration of a vertical waveguide feed, in accordance with an embodiment.

FIGS. 8A-8H are cross-sectional illustrations depicting a process for assembling a vertical waveguide feed, in accordance with an embodiment.

FIG. 9 is a cross-sectional illustration of an electronic system that includes a communication module with an array of 3D communication dies, in accordance with an embodiment.

FIG. 10 is a schematic of a computing device built in accordance with an embodiment.

### EMBODIMENTS OF THE PRESENT DISCLOSURE

Described herein are electronic systems, and more particularly, communication modules with three-dimensional antenna arrays, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, the move to smaller wavelength wireless communications (e.g., mm-wave communications or sub-terahertz (sub-THz) communications) is resulting in integration complexity increases. For example, in antenna array configurations used for beam forming, the antennas are typically spaced at a pitch that is equal to half the wavelength 2. As this pitch decreases, it becomes more difficult to fit the driving circuitry within the array. More specifically, the size of the driving circuitry needs to be less than the antenna pitch in order to fit the driving circuitry within the array.

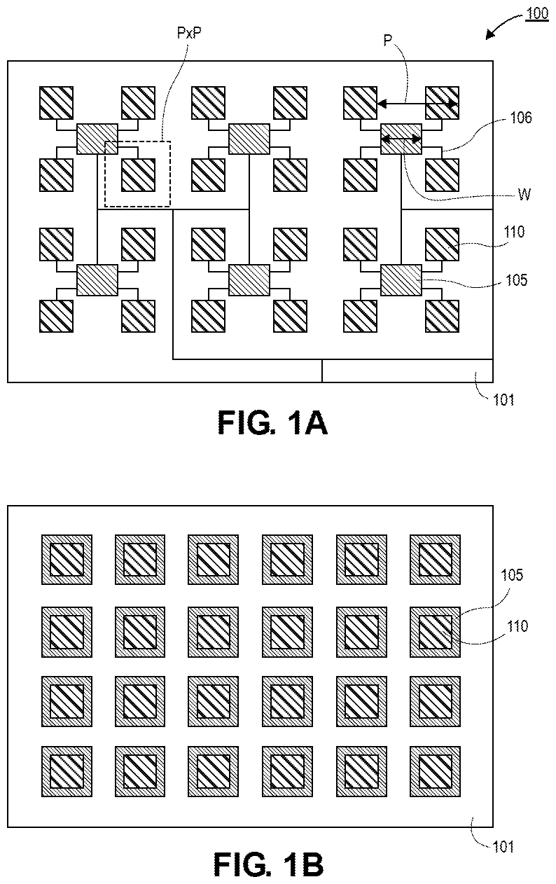

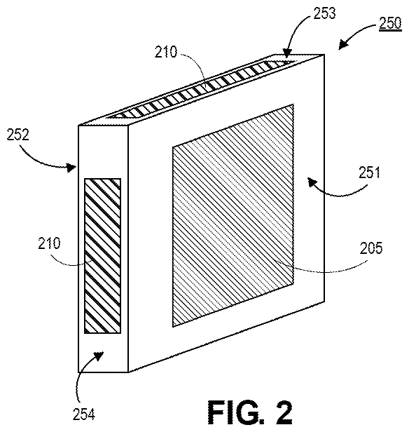

An example of such a configuration is shown in FIG. 1A. A communication module 100 is shown in FIG. 1A. The communication module 100 may include a substrate 101. For example, the substrate 101 may be a semiconductor die, such as a silicon die. An array of antennas 110 may be distributed across the surface of the substrate 101. The antennas 110 may be spaced at a pitch P. As noted above, the pitch P is typically one-half of the operating wavelength of the communication module 100 and antennas 110. The antennas 110 may be any sort of antenna structure. For example, the antennas 110 may be patch antennas, dipole antennas, or Vivaldi antennas in some instances.

The antennas 110 may be communicatively coupled to driving circuitry 105 that is fabricated on the substrate 101 by interconnects 106. The driving circuitry 105 may include Tx and/or Rx functionality. In some instances, the driving circuitry 105 may be referred to as a transceiver die. The driving circuitry 105 may be interleaved within the array of antennas 110. For example, each set of four antennas 110 surround one instance of the driving circuitry 105 in FIG. 1A. In order for the driving circuitry 105 to fit within the array, the dimensions of the driving circuitry 105 need to be smaller than the pitch P. For example, a width W of the driving circuitry 105 is smaller than the pitch P in FIG. 1A. Similarly, the height of the driving circuitry 105 is also smaller than the pitch P in FIG. 1A.

In other embodiments, as shown in FIG. 1B, each instance of the driving circuitry 105 may be underlying a single antenna 110. That is, the driving circuitry 105 and the antennas 110 may be in a one-to-one relationship with each other. The driving circuitry 105 may be embedded in the substrate 101, such as a semiconductor substrate. In an embodiment, the driving circuitry 105 may have a footprint that is PxP, where P is one half of the operating wavelength.

Such configurations are fine when the operational wavelength of the antennas 110 is sufficiently large. However, as the wavelength decreases (as is the case with mm-wave and sub-THz communications) the pitch P is reduced so much that the driving circuitry 105 no longer fits within the array of antennas 110. As such, traditional two-dimensional approaches are no longer feasible, and alternative integration approaches are necessary.

Accordingly, embodiments disclosed herein include the use of three-dimensional (3D) communication dies. In the case of a 3D communication die, the size of the driving circuitry is decoupled from the operational wavelength of the antennas. That is, the pitch between antennas can continue to scale down to smaller and smaller pitches without the size of the driving circuitry impacting the layout. This allows for higher frequency communications, which can increase bandwidths.

The 3D communication die may include a first surface and a second surface. Edge surfaces may couple the first surface to the second surface. In an embodiment, one or both of the first surface and the second surface may comprise an area for the driving circuitry, and antennas can be provided along the edge surfaces. Multiple 3D communication dies can be arranged in an array with each die having first and second faces that are parallel to each other. The first and second faces may be perpendicular to an underlying base die onto which the 3D communication dies are mounted. The 3D communication dies may be spaced at a pitch that is substantially equal to one-half the wavelength of the antennas.

The 3D communication dies may include antennas on three of the edge surfaces. This provides better coverage for the array of antennas, as opposed to using purely beam forming solutions. For example, beam emissions may be provided in the z half space as well as the +x half space and the −x half space when using such a 3D configuration. In contrast, a planar 2D array will only provide beam emissions in the z half space.

In some instances, one antenna is provided along each of the edge surfaces. In other embodiments, two or more antennas are provided along each of the edge surfaces. In some instances, adjacent 3D communication dies may have antennas that are offset from each other by an offset of one-half A. This enables the generation of a 2D phase array on each of the three edge surfaces.

One of the advantages of using such a 3D architecture is that the material of the communication die can be different than the material of the base die. For example, the base die may comprise a standard silicon material suitable for fabrication of CMOS circuitry. In contrast, the 3D communication dies can be optimized for high frequency applications. For example, group III-V semiconductors may be used for each of the 3D communication dies.

In other embodiments, vertically oriented 3D architectures can be used with waveguide solutions. In such embodiments, vertically oriented semiconductor substrates and waveguides are interleaved with each other. An electromagnetic signal launcher array can be provided over ends of the semiconductor substrates and the waveguides in order to propagate signals along the waveguide. As such, embodiments are not limited to traditional antenna architectures.

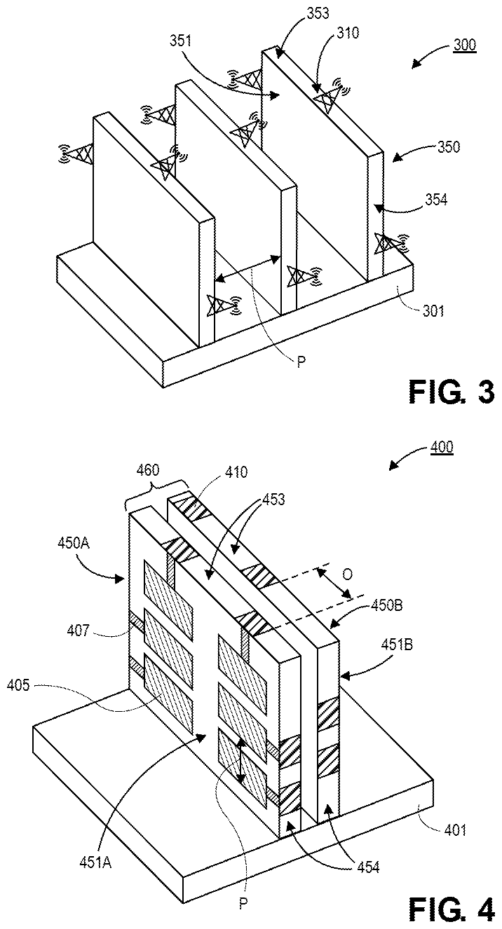

Referring now to FIG. 2, a perspective view illustration of a communication die 250 is shown, in accordance with an embodiment. In an embodiment, the communication die 250 comprises a semiconductor substrate. For example, the semiconductor substrate may be a group III-V semiconductor. Such an embodiment may be particularly beneficial for high frequency operations. Though, other semiconductor materials may also be used in some instances.

The communication die 250 may include a first surface 251 and a second surface 252 opposite from the first surface 251. The first surface 251 may be coupled to the second surface 252 by edge surfaces. For example, edge surfaces 253 and 254 are visible in FIG. 2. The first surface 251 and the second surface 252 may have areas that are larger than individual ones of the edge surfaces 253 or 254.

In an embodiment, the communication die 250 may include circuitry element 205, also referred to simply as “circuitry” in some instances. A circuitry element may include one or more active (transistors, etc.) or passive (resistor, capacitor, etc.) electrical components that are used in isolation and/or in combination in order to function with a desired purpose. The circuitry 205 may be circuitry for driving antennas. For example, the circuitry 205 may be Tx/Rx circuitry of a transceiver. In the illustrated embodiment, the circuitry 205 is shown as a single block. Though, it is to be appreciated that the circuitry 205 may be segmented into regions for each individual antenna 210. For example, each antenna 210 may be serviced by different driving circuitry blocks. The circuitry 205 may be provided on the first surface 251 and/or the second surface 252.

In an embodiment, the circuitry 205 may have any dimension. More particularly, a width of the circuitry 205 may be larger than half the wavelength λ of the antennas 210. For example, the width of the circuitry 205 may be up to approximately 10 mm in some embodiments, up to approximately 5 mm, or up to approximately 2 mm. Due to the 3D architecture with the circuitry 205 on the first surface 251 and/or the second surface 252, the size of the circuitry 205 does not interfere with the formation of arrays of antennas, as will be described in greater detail below.

In an embodiment, antennas 210 may be provided on the edge surfaces of the communication die 250. For example, antennas 210 are shown on the edge surface 253 and the edge surface 254 in FIG. 2. The hidden surface opposite from edge surface 254 may also have an antenna 210. That is, embodiments may include three antennas 210 on the communication die 250. The antennas 210 may be any suitable antenna configuration. For example, the antennas 210 may be patch antennas or any other antenna architecture.

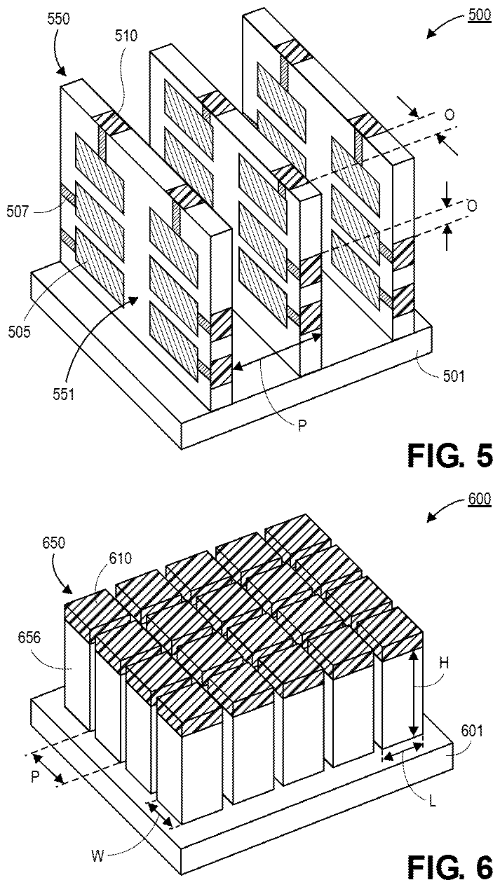

Referring now to FIG. 3, a perspective view illustration of a communication module 300 is shown, in accordance with an embodiment. As shown, the communication module 300 comprises a base die 301. Communication dies 350 may extend up from the base die 301. In an embodiment, the base die 301 and the communication dies 350 comprise different semiconductor materials. For example, the base die 301 may comprise silicon, and the communication dies 350 may comprise a group III-V semiconductor material suitable for high frequency operation. In an embodiment, standard CMOS circuitry may be provided on the base die 301, and driving circuitry (not shown) may be provided on the communication dies 350.

In an embodiment, the communication dies 350 may comprise a first surface 351 and edge surfaces 353 and 354. The first surface 351 may be oriented so that it is substantially orthogonal to the surface of the base die 301 on which the communication dies 350 are mounted. The area of the first surface 351 may be larger than areas of either the edge surface 353 or the edge surface 354. In an embodiment, the driving circuitry may be provided on the first surfaces 351 of the communication dies 350.

As shown, a plurality of antennas 310 are provided on each communication die 350. For example, antennas 310 are provided on edge surface 353, edge surface 354, and a backside edge surface opposite from edge surface 354. Each antenna 310 may be coupled to driving circuitry on the communication die 350. The antennas 310 may be patch antennas or the like.

In an embodiment, the communication dies 350 may be spaced apart from each other with a pitch P. The pitch P may be one-half the operating wavelength λ of the antennas 310. For example, the pitch P may be approximately 10 mm or less, or approximately 5 mm or less, or approximately 1 mm or less. As used herein, “approximately” refers to a range of values within ten percent of the stated value. For example, approximately 10 mm refers to a range of values between 9 mm and 11 mm.

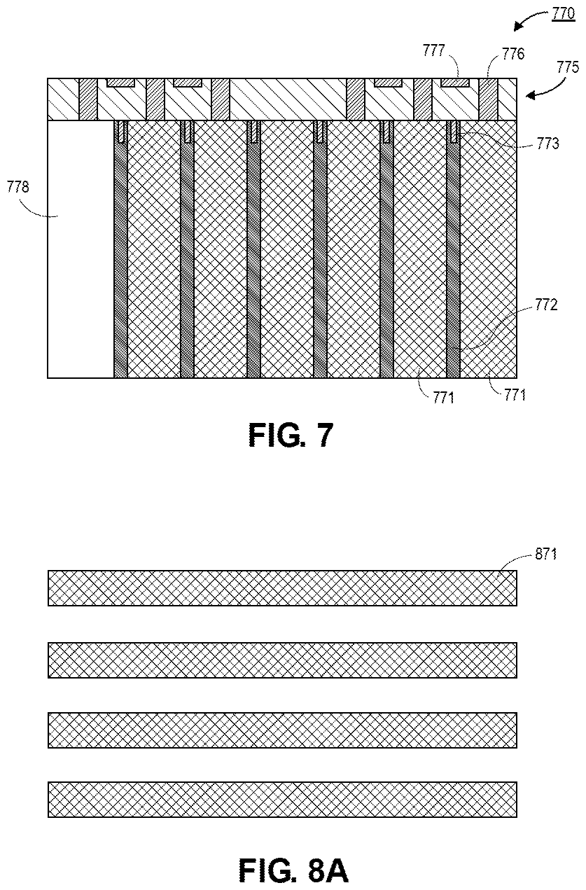

Referring now to FIG. 4, a perspective view illustration of a communication module 400 is shown, in accordance with an additional embodiment. In an embodiment, the communication module 400 includes the formation of 2D planar arrays on each edge surface. This allows for the inclusion of three antenna arrays facing different directions within a single communication module 400.

The communication module 400 may include a base die 401 with communication dies 450 extending up from the base die 401. In a particular embodiment, the communication dies 450 are grouped into a pair 460. The pair 460 includes communication die 450A and communication die 450B. In some embodiments, the communication dies 450A and 450B may be spaced apart from each other. In other embodiments, the communication dies 450A and 450B may be bonded together.

The communication dies 450A and 450B may be arranged in a back-to-back configuration. For example, first surfaces 451A and 451B face away from each other. Accordingly, driving circuitry 405 on each communication die 450A and 450B face away from each other as well. In an embodiment, the communication dies 450A and 450B may include a plurality of instances of the circuitry 405. For example, six instances of the circuitry 405 may be provided on each communication die 450A and 450B. The circuitry 405 may be connected to antennas 410 through interconnects 407. In an embodiment, a plurality of antennas 410 are provided on the communication dies 450A and 450B. For example, edge surfaces 453 and 454 may each have one or more antennas 410. As shown in FIG. 4, a pair of antennas 410 are provided on each of the edge surfaces 453 and 454.

In an embodiment, the circuitry 405 may be spaced apart from each other by a pitch P. In order to accommodate larger circuitry 405, the pitch P may be greater than half the wavelength λ of the antennas 410. In a particular embodiment, the pitch P may be approximately equal to a wavelength λ of the antennas 410. Though, the pitch P may also be larger. This results in the corresponding antennas 410 to also be spaced at a pitch that is greater than half the wavelength λ of the antennas 410. Such an array will not provide the necessary spacing to enable the desired signal propagation, beam forming, etc.

Accordingly, embodiments include offsetting the antennas 410 on adjacent communication dies 450. For example, the antennas 410 on the die 450B may be offset by an offset O from the antennas 410 on the die 450A. In an embodiment, the offset O is equal to one-half of the wavelength of the antennas 410. As such, a four-by-one array is provided on each edge surface of the pair 460. By providing multiple pairs 460 spaced at a pitch of one-half 2, an array with any desired size may be provided.

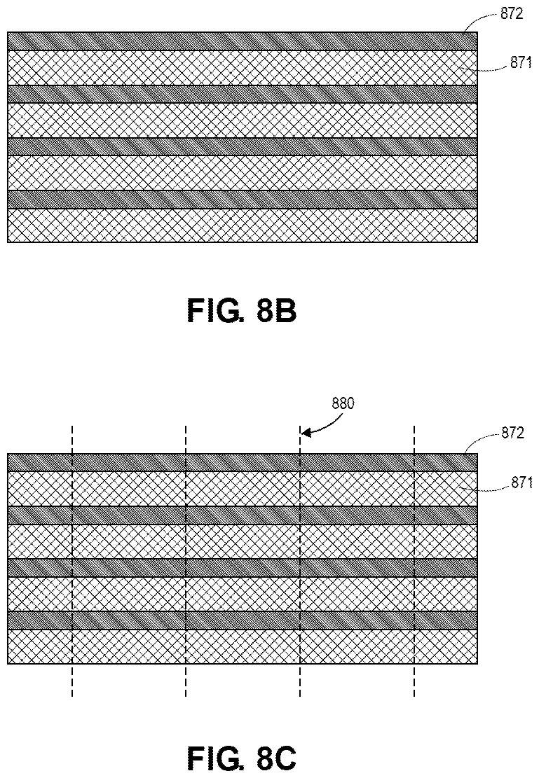

Referring now to FIG. 5, a perspective view illustration of a communication module 500 is shown, in accordance with an additional embodiment. In an embodiment, the communication module 500 may also allow for 2D integration along edges of the compute dies 550. However, the die-to-die integration complexity is reduced since there is no tight pitch stacking or die-to-die stacking, as is the case in the embodiment shown in FIG. 4.

In an embodiment, the communication module 500 may include a base die 501. A plurality of communication dies 550 may be attached to the base die 501. The base die 501 and the communication dies 550 may be different semiconductor materials. Each of the base dies 501 may include circuitry 505. The circuitry 505 may be provided on a faces of the communication dies 550 that are orthogonal to the surface of the base die 501 on which the communication dies 550 are supported.

In an embodiment, the circuitry 505 may be electrically coupled to antennas 510 by interconnects 507. In an embodiment, two or more antennas 510 may be provided on each of the edge surfaces of the communication dies 550. The antennas 510 on a single communication die 550 may be spaced at a distance equal to the wavelength λ of the antennas 510. In an embodiment neighboring communication dies 550 may include antennas 510 that are offset by an offset O. For example, the offset O may be one-half the wavelength λ of the antennas 510. As such, a 2D array of antennas 510 spaced at 22 is provided along each edge of the communication module 500. The communication dies 550 may be spaced at a pitch P. For example, the pitch P may be one-fourth the wavelength λ of the antennas 510. As such, for each row of antennas 510, the antennas are spaced at N/λ.

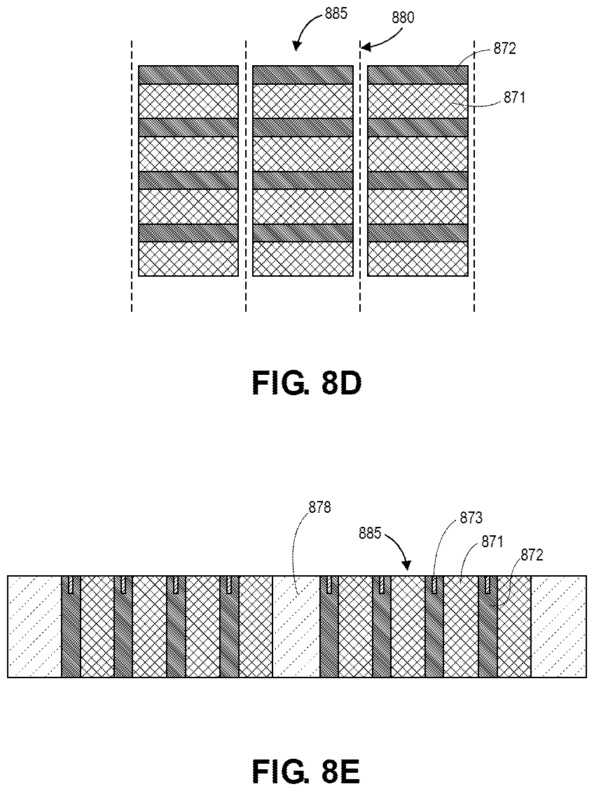

Referring now to FIG. 6, a perspective view illustration of a communication module 600 is shown, in accordance with an embodiment. In an embodiment, the communication module 600 includes a base die 601. A plurality of communication dies 650 may be provided over the base die 601. The communications dies 650 may comprise a different semiconductor material than the base die 601. For example, the communication dies 650 may include a group III-V semiconductor 656 and the base die 601 may comprise silicon. In an embodiment, the communication dies 650 may be spaced at a pitch P. In an embodiment, the pitch P may be smaller than half the wavelength λ of the antennas 610. Such an embodiment allows for compact arrays without regard to the size of the circuitry needed to drive the antennas 610. That is, the size of the driving circuitry is decoupled from the pitch P of the array.

In an embodiment, each communication die 650 may include a footprint with a length L and a width W. The length L and width W may be suitable to fit the communication dies 650 within the limited pitch P. However, the available area on the communication dies 650 is not limited since the height H is a free parameter. The height H can be extended to any desired dimension in order to fit the driving circuitry for the overlying antennas 610. Further, while the communication dies 650 are shown with vertical sidewalls, it is to be appreciated that in some embodiments, the sidewalls may be sloped. For example, the communication dies 650 may not be orthogonal to the base die 601 in some embodiments. Angled architectures may preserve space for circuitry while also minimizing the total Z-height of the communication module 600.

In the embodiments disclosed above, 3D antenna architectures are described. However, embodiments are not limited to antenna architectures. For example, propagation of signals through solid or flexible waveguides can also benefit from 3D architectures. Particularly, the size of the waveguide launcher is also defined by half the wavelength of the system operation. For example, at 110 GHz to 170 GHz, a waveguide launcher may be approximately 1 mm by 2 mm, and at 260 GHz the waveguide launcher may be approximately 1 mm by 0.5 mm. At even larger sub-THz frequencies, the area occupied by the launcher can reach deep sub-mm ranges and can fall below the size of typical Tx and Rx circuits, which results in complicated wiring and additional losses.

In some instances, waveguide feeds are fabricated. The waveguides may be interdigitated with semiconductor bodies that extend along a length of the waveguides. The unconfined length dimension of the cubes allows for the circuitry to be fabricated with any area, while still maintaining the necessary dimensions of the waveguide launchers.

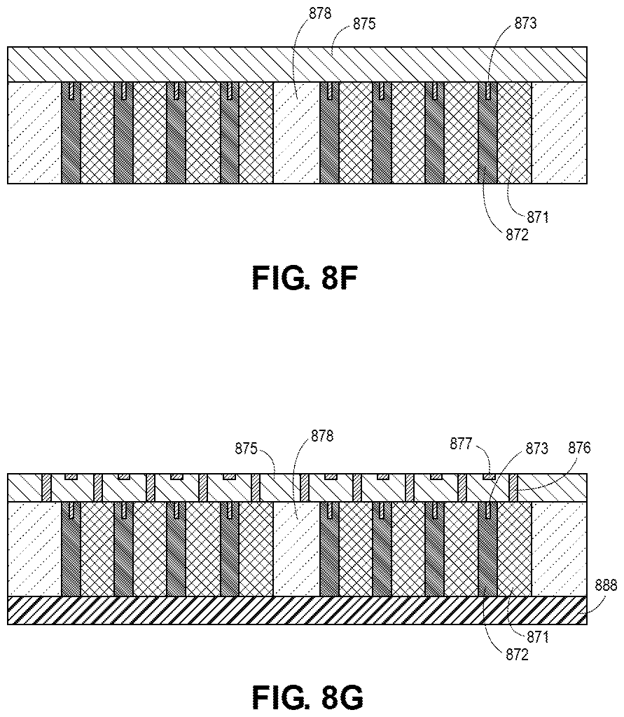

An example of such an embodiment is shown in the cross-sectional illustration of FIG. 7. In an embodiment, the waveguide feed 770 comprises a waveguide launcher layer 775. The waveguide launcher layer 775 may include shielding structures 776 on either side of a waveguide launcher (or antenna) 777. The waveguide launcher 777 may be a patch, a slot based launcher, a monopole launcher, a dipole launcher, or the like. In an embodiment, semiconductor bodies 771 may be provided below the waveguide launcher layer 775. The semiconductor bodies 771 may comprise the driving circuitry for the waveguide launcher 777. Since there is an unconfined height dimension to the semiconductor bodies 771, the size of the driving circuitry is not limited by the size or pitch of the waveguide launchers 777. In an embodiment feed lines 773 provide a conductive pathway to connect the driving circuitry of the semiconductor bodies 771 with the waveguide launchers 777. Interface layers 772 may be provided between the semiconductor bodies 771. In an embodiment, the structure may be embedded in a dielectric layer 778, such as a mold layer 778.

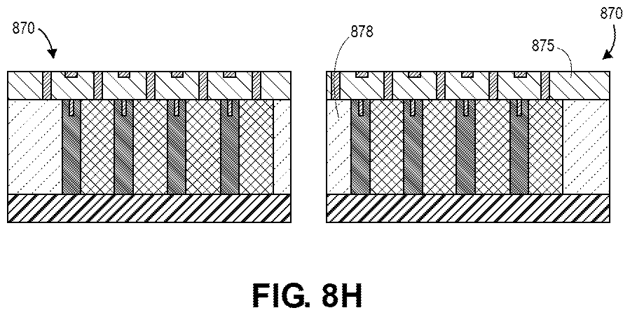

Referring now to FIGS. 8A-8H, a series of cross-sectional illustrations depicting a process for forming a waveguide feed is shown, in accordance with an embodiment. In an embodiment, the waveguide feed in FIG. 8A-8H may be similar to the waveguide feed 770 described above with respect to FIG. 7.

Referring now to FIG. 8A, a cross-sectional illustration of the waveguide feed at a stage of manufacture is shown, in accordance with an embodiment. In an embodiment, a plurality of semiconductor wafers 871 are prepared. The wafers 871 may include circuitry for driving one or more antennas or electromagnetic signal launchers. Dicing in a subsequent operation may isolate one region of circuitry for each waveguide feed. In the illustrated embodiment, four wafers 871 are provided as an example. However, it is to be appreciated that any number of wafers 871 may be used. Additionally, it is to be appreciated that operations, such as thinning, polishing, etc. may be used. While shown as having substantially the same thicknesses, it is to be appreciated that the wafers 871 may have different thicknesses.

Referring now to FIG. 8B, a cross-sectional illustration of the waveguide feed at a different stage of manufacture is shown, in accordance with an embodiment. The wafers 871 may be bonded to each other in a stack. Additionally, a plurality of interface layers 872 may be provided between the wafers 871. The interface layers 872 may comprise any dielectric, ceramic, conductive material (e.g., metal), or be a hybrid of any such materials. Referring now to FIG. 8C, a cross-sectional illustration of the waveguide feed at a different stage of manufacture is shown, in accordance with an embodiment. As shown by the dashed lines 880, the stack is segmented into a plurality of regions. Each of the regions may include a single instance of the driving circuitry in each wafer 871. That is, in each region shown in FIG. 8C, there may be four instances of the driving circuitry (one in each layer). Three full regions are shown in FIG. 8C, and portions of two more regions (at the edges of FIG. 8C) are shown.

Referring now to FIG. 8D, a cross-sectional illustration of the stack after singulation is shown, in accordance with an embodiment. In an embodiment, the singulation may isolate each region 885. The partial regions in FIG. 8C are omitted for simplicity. In an embodiment, the singulation may be done with any suitable singulation process, such as sawing, etching, plasma dicing, laser ablation, combinations of the two, or the like.

Referring now to FIG. 8E, a cross-sectional illustration of a reconstituted wafer with a plurality of regions 885 is shown, in accordance with an embodiment. Each region may be rotated ninety degrees from the orientation shown in FIG. 8D. After rotation, the regions 885 may be embedded in a dielectric layer 878. The dielectric layer may be a mold material, an oxide material, or any other suitable material. In the rotated orientation, the ends of the interface layers 872 and wafers 871 are exposed. Also shown in FIG. 8E is the stem 873. The feed lines 873 may be added at this operation, the feed lines 873 may be added in a previous operation, or the feed lines 873 may be added in a subsequent operation. The feed lines 873 may be a conductive pathway to connect the driving circuitry with the subsequently formed antenna or launcher.

Referring now to FIG. 8F, a cross-sectional illustration of the reconstituted wafer after a waveguide launcher layer 875 is provided is shown, in accordance with an embodiment. The waveguide launcher layer 875 may be a dielectric layer or the like. The waveguide launcher layer 875 may be provided over the ends of the interface layers 872 and the wafers 871, as well as over the dielectric layer 878.

Referring now to FIG. 8G, a cross-sectional illustration of the reconstituted wafer after the launcher architecture is provided is shown, in accordance with an embodiment. In an embodiment, the launcher architecture may include shielding structures 876 that isolate each launching region. Additionally waveguide launchers 877 may be provided above the interface layers 872. The waveguide launchers 877 may communicatively couple with the feed lines 873 in order to launch signals along the interface layers 872. In an embodiment, an attachment layer 888 may also be provided along a bottom surface of the reconstituted wafer. The attachment layer 888 may be used to attach the completed waveguide cube to an underlying base die or other structure.

In an embodiment, the interface layers 872 may also be coupling layers. That is, one or more of the interface layers 872 may comprise communicative coupling features (e.g., traces, vias, etc.) that provide the communicative coupling from the wafers 871 to the underlying base die substrate. For example, the base die may include I/O features, power delivery, or the like.

Referring now to FIG. 8H, a cross-sectional illustration of the reconstituted wafer after singulation to form a waveguide cube 870 is shown, in accordance with an embodiment. In an embodiment, the singulation may be a sawing process, a laser ablation process, a combination thereof, or the like. In an embodiment, the waveguide cube 870 includes vertically oriented interface layers 872 with neighboring portions of semiconductor wafers 871 that house the driving circuitry for the interface layers 872.

While referred to as a “cube” it is to be appreciated that the waveguide cube 870 need not have outer dimensions that result in a true cube shape. For example, the waveguide cube 870 may be more generally referred to as being a rectangular prism.

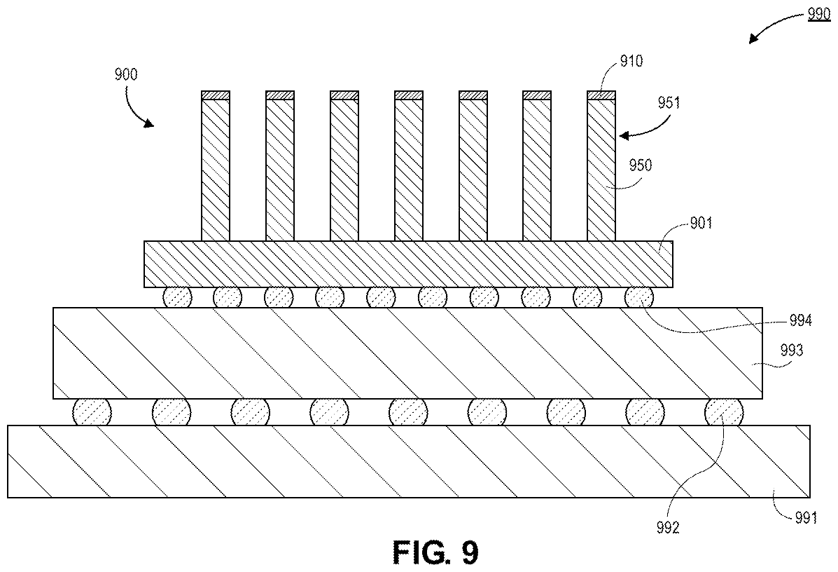

Referring now to FIG. 9, a cross-sectional illustration of an electronic system 990 is shown, in accordance with an embodiment. In an embodiment, the electronic system 990 comprises a board 991, such as a printed circuit board (PCB). The board 991 may be coupled to a package substrate 993 by interconnects 992. The interconnects 992 may be solder balls, sockets, or the like. In an embodiment, a communication module 900 is coupled to the package substrate 993 by interconnects 994. The interconnects 994 may be any first level interconnect (FLI) architecture.

In an embodiment, the communication module 900 comprises a base die 901 with a plurality of communication dies 950 supported on the base die 901. A connection between the base die 901 and the communication dies 950 may be any suitable interconnect architecture. In an embodiment, the communication dies 950 may be similar to any of the communication dies 950 described herein. For example, one or more of the edge surfaces of the communication dies 950 may include an antenna 910. Driving circuitry for the one or more antennas 910 may be provided on a first surface 951 of the communication dies 950 or elsewhere on the communication dies 950. Such a configuration allows for 3D architectures that enable scaling to wavelengths smaller than the achievable footprint of the driving circuitry, as described above. Accordingly, improved scalability is provided.

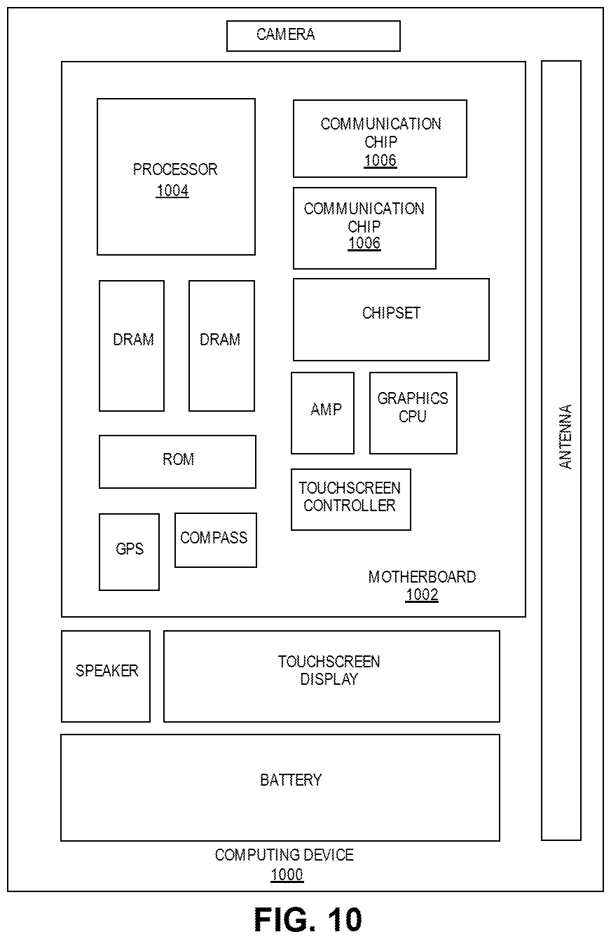

FIG. 10 illustrates a computing device 1000 in accordance with one implementation of the invention. The computing device 1000 houses a board 1002. The board 1002 may include a number of components, including but not limited to a processor 1004 and at least one communication chip 1006. The processor 1004 is physically and electrically coupled to the board 1002. In some implementations the at least one communication chip 1006 is also physically and electrically coupled to the board 1002. In further implementations, the communication chip 1006 is part of the processor 1004.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1006 enables wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing device 1000 includes an integrated circuit die packaged within the processor 1004. In some implementations of the invention, the integrated circuit die of the processor may be part of a communication module that includes a base die with vertically oriented communication dies that enable one or more antenna arrays, in accordance with embodiments described herein. The term “processor” may refer to any device or portion of a device that processes electronic data from registers and/or memory to transform that electronic data into other electronic data that may be stored in registers and/or memory.

The communication chip 1006 also includes an integrated circuit die packaged within the communication chip 1006. In accordance with another implementation of the invention, the integrated circuit die of the communication chip may be part of a communication module that includes a base die with vertically oriented communication dies that enable one or more antenna arrays, in accordance with embodiments described herein.

In an embodiment, the computing device 1000 may be part of any apparatus. For example, the computing device may be part of a personal computer, a server, a mobile device, a tablet, an automobile, or the like. That is, the computing device 1000 is not limited to being used for any particular type of system, and the computing device 1000 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a communications die, comprising: a substrate with a first face and a second face, and wherein edge surfaces connect the first face to the second face; a circuitry element on the first face; and an antenna on at least one of the edge surfaces.

Example 2: the communications die of Example 1, wherein the circuitry element comprises circuitry for driving the antenna.

Example 3: the communications die of Example 1 or Example 2, wherein the substrate comprises a group III-V semiconductor material.

Example 4: the communication die of Examples 1-3, further comprising: a plurality of antennas, each on a different one of the edge surfaces.

Example 5: the communication die of Examples 1-4, wherein the antenna is a mm-wave antenna or a sub-terahertz antenna.

Example 6: the communication die of Examples 1-5, further comprising: a base die that is a CMOS logic chip, wherein the substrate is coupled to the base die.

Example 7: the communication die of Example 6, wherein a connection from the circuitry element to the antenna is across one of the edge surfaces.

Example 8: a communication module, comprising: a base die with a first surface and a second surface; an array of communication dies on the base die, and wherein individual ones of the communication dies comprise: a third surface that is orthogonal to the first surface of the base die; a fourth surface that is orthogonal to the first surface of the base die; edge surfaces to couple the third surface to the fourth surface; circuitry elements on the third surface; and an antenna on one or more of the edge surfaces.

Example 9: the communication module of Example 8, wherein the communication dies are spaced at a pitch.

Example 10: the communication module of Example 9, wherein a width of one or more of the circuitry elements is larger than the pitch.

Example 11: the communication module of Example 10, wherein the width of the circuitry element is at least 1.5 times the pitch.

Example 12: the communication module of Examples 8-11, wherein the array of communication dies comprises a first die and a second die, wherein the first die is adjacent to the second die, wherein the first die comprises a first antenna; and wherein the second die comprises a second antenna, wherein an edge of the first antenna is offset from an edge of the second antenna by a distance of half a pitch between adjacent communication dies.

Example 13: the communication module of Examples 8-12, wherein each communication die comprises two or more antennas along each of the edge surfaces, and wherein the circuitry elements on the first surface comprises a number of driving circuitry instances equal to a number of antennas.

Example 14: the communication module of Examples 8-13, wherein a first communication die and a second communication die are oriented in a back-to-back configuration so that the first surfaces face away from each other.

Example 15: the communication module of Example 14, wherein a first antenna on the first communication die is offset from a second antenna on the second communication die.

Example 16: the communication module of Examples 8-15, further comprising: a package substrate coupled to the base die; and a board coupled to the package substrate.

Example 17: the communication module of Example 16, wherein the communication module is part of a personal computer, a server, a mobile device, a tablet, or an automobile.

Example 18: a waveguide module, comprising: a first semiconductor layer; a waveguide adjacent to the first semiconductor layer; a second semiconductor layer adjacent to the waveguide; and a waveguide launcher structure over edges of the first semiconductor layer, the waveguide, and the second semiconductor layer.

Example 19: the waveguide module of Example 18, wherein the waveguide module is embedded in a mold layer.

Example 20: the waveguide module of Example 18 or Example 19, wherein the first semiconductor layer and/or the second semiconductor layer comprise driving circuitry.

What is claimed is:

1. A communications die, comprising:
a substrate with a first face and a second face, and wherein edge surfaces connect the first face to the second face;
a circuitry element on the first face; and
an antenna on at least one of the edge surfaces.

2. The communications die of claim 1, wherein the circuitry element comprises circuitry for driving the antenna.

3. The communications die of claim 1, wherein the substrate comprises a group III-V semiconductor material.

4. The communication die of claim 1, further comprising:
a plurality of antennas, each on a different one of the edge surfaces.

5. The communication die of claim 1, wherein the antenna is a mm-wave antenna or a sub-terahertz antenna.

6. The communication die of claim 1, further comprising:
a base die that is a CMOS logic chip, wherein the substrate is coupled to the base die.

7. The communication die of claim 6, wherein a connection from the circuitry element to the antenna is across one of the edge surfaces.

8. A communication module, comprising:
a base die with a first surface and a second surface;
an array of communication dies on the base die, and wherein individual ones of the communication dies comprise:
a third surface that is orthogonal to the first surface of the base die;
a fourth surface that is orthogonal to the first surface of the base die;
edge surfaces to couple the third surface to the fourth surface;
circuitry elements on the third surface; and
an antenna on one or more of the edge surfaces.

9. The communication module of claim 8, wherein the communication dies are spaced at a pitch.

10. The communication module of claim 9, wherein a width of one or more of the circuitry elements is larger than the pitch.

11. The communication module of claim 10, wherein the width of the circuitry element is at least 1.5 times the pitch.

12. The communication module of claim 8, wherein the array of communication dies comprises a first die and a second die, wherein the first die is adjacent to the second die,
wherein the first die comprises a first antenna; and
wherein the second die comprises a second antenna, wherein an edge of the first antenna is offset from an edge of the second antenna by a distance of half a pitch between adjacent communication dies.

13. The communication module of claim 8, wherein each communication die comprises two or more antennas along each of the edge surfaces, and wherein the circuitry elements on the first surface comprises a number of driving circuitry instances equal to a number of antennas.

14. The communication module of claim 8, wherein a first communication die and a second communication die are oriented in a back-to-back configuration so that the first surfaces face away from each other.

15. The communication module of claim 14, wherein a first antenna on the first communication die is offset from a second antenna on the second communication die.

16. The communication module of claim 8, further comprising:
a package substrate coupled to the base die; and
a board coupled to the package substrate.

17. The communication module of claim 16, wherein the communication module is part of a personal computer, a server, a mobile device, a tablet, or an automobile.

18. A waveguide module, comprising:
a first semiconductor layer;
a waveguide adjacent to the first semiconductor layer;
a second semiconductor layer adjacent to the waveguide; and
a waveguide launcher structure over edges of the first semiconductor layer, the waveguide, and the second semiconductor layer.

19. The waveguide module of claim 18, wherein the waveguide module is embedded in a mold layer.

20. The waveguide module of claim 18, wherein the first semiconductor layer and/or the second semiconductor layer comprise driving circuitry.
